(19) United States
(12) Patent Application Publication
(10) Pub. No.: US 2025/0015134 A1
(43) Pub. Date: Jan. 9, 2025

(54) SEMICONDUCTOR DEVICES AND METHOD OF MANUFACTURING THE SAME

(71) Applicant: SAMSUNG ELECTRONICS CO., LTD., SUWON-SI (KR)

(72) Inventors: Changju Moon, Suwon-si (KR); Donggwan Shin, Suwon-si (KR); Yonghee Park, Suwon-si (KR); Myunggil Kang, Suwon-si (KR); Jeongho Yoo, Suwon-si (KR)

(21) Appl. No.: 18/676,686

(22) Filed: May 29, 2024

(30) Foreign Application Priority Data
Jul. 4, 2023 (KR) 10-2023-0086274

(51) Int. Cl. H01L 29/08; H01L 29/423; H01L 29/66; H01L 29/78

(52) U.S. Cl. CPC H01L 29/0847; H01L 29/42392; H01L 29/785; H01L 29/66795

(57) ABSTRACT

A semiconductor device includes an active region that extends on the substrate in a first direction; a plurality of semiconductor layers disposed on the active region and that are spaced apart from each other in a vertical direction perpendicular to an upper surface of the substrate; a gate structure disposed on the substrate and that crosses the active region and the plurality of semiconductor layers, surrounds each of the plurality of semiconductor layers, and extends in a second direction; a source/drain region disposed on at least one side of the gate structure and in contact with a portion of the plurality of semiconductor layers; and an epitaxial layer that is spaced apart from an uppermost semiconductor layer, is disposed below the source/drain region and between the active region and the source/drain region, and is in contact with at least a portion of the side surfaces of the lowermost semiconductor layer.

### CROSS-REFERENCE TO RELATED APPLICATION(S)

This application claims priority under 35 U.S.C. 119 from Korean Patent Application No. 10-2023-0086274, filed on Jul. 4, 2023 in the Korean Intellectual Property Office, the contents of which are herein incorporated by reference in their entirety.

### TECHNICAL FIELD

Embodiments are directed to a semiconductor device and a method of manufacturing the same.

### DISCUSSION OF THE RELATED ART

As demands for high performance, high speed, and/or multifunctionality of a semiconductor device increase, integration density of semiconductor devices has increased. In manufacturing a semiconductor device that has fine patterns for high integration density of a semiconductor device, patterns having a fine width or a fine spacing distance may need to be implemented. In addition, there have been efforts to develop a semiconductor device that has a three-dimensional structure channel to overcome limitations in operating properties caused by reduction of a size of a planar metal oxide semiconductor FET (MOSFET).

### SUMMARY

Embodiments provide a semiconductor device that has increased electrical properties.

According to an embodiment, a semiconductor device includes an active region that extends on the substrate in a first direction; a plurality of semiconductor layers disposed on the active region and that are spaced apart from each other in a vertical direction perpendicular to an upper surface of the substrate; a gate structure disposed on the substrate and that crosses the active region and the plurality of semiconductor layers, surrounds each of the plurality of semiconductor layers, and extends in a second direction that crosses the first direction; a source/drain region disposed on at least one side of the gate structure and in contact with a portion of the plurality of semiconductor layers; and an epitaxial layer that is spaced apart from an uppermost semiconductor layer of the plurality of semiconductor layers, is disposed below the source/drain region and between the active region and the source/drain region, and is in contact with at least a portion of the side surfaces of a lowermost semiconductor layer of the plurality of semiconductor layers.

According to embodiment, a semiconductor device includes an active region that extends on the substrate in a first direction; a plurality of semiconductor layers disposed on the active region and that are spaced apart from each other in a vertical direction perpendicular to an upper surface of the substrate; a gate structure disposed on the substrate and that crosses the active region and the plurality of semiconductor layers, surrounds each of the plurality of semiconductor layers, and extends in a second direction that crosses the first direction; source/drain regions disposed on at least one side of the gate structure and in contact with at least a portion of the plurality of semiconductor layers; and epitaxial layers disposed between the active region and the source/drain regions, respectively. The source/drain regions include a first source/drain region and a second source/drain region disposed on each side of the gate structure, and the epitaxial layers are recessed into the active region and extend from an upper surface of the active region to a lower surface of the source/drain regions.

According to an embodiment, a semiconductor device includes a substrate that includes a first region and a second region; an active region that extends on the substrate in a first direction; a plurality of semiconductor layers disposed on the active region and that spaced apart from each other in a vertical direction perpendicular to an upper surface of the substrate; a gate structure disposed on the substrate and that crosses the active region and the plurality of semiconductor layers, surrounds each of the plurality of semiconductor layers, and extends in a second direction that crosses the first direction; source/drain regions disposed on at least one side of the gate structure and in contact with at least a portion of the plurality of semiconductor layers; and epitaxial layers disposed between the active region and the source/drain regions, respectively. In the first region, the source/drain regions have a first depth in the vertical direction, and in the second region, the source/drain regions have a second depth in the vertical direction that differs from the first depth. A number of the plurality of semiconductor layers that electrically connect the source/drain regions to each other in the first region differs from a number of the plurality of semiconductor layers that electrically connect the source/drain regions to each other in the second region, and the epitaxial layers are recessed into the active region and extend from an upper surface of the active region to a lower surface of the source/drain regions.

According to an embodiment, a method of manufacturing a semiconductor device includes forming an active region that extends in a first direction on a substrate that includes a first region and a second region; alternately stacking sacrificial layers and a plurality of semiconductor layers on the active region in a vertical direction perpendicular to an upper surface of the substrate; forming an active structure by removing a portion of the sacrificial layers and the plurality of semiconductor layers; forming sacrificial gate structures on the active structure and that extend in a second direction that crosses the first direction; forming a recess region by removing a portion of the sacrificial layers and the plurality of semiconductor layers between the sacrificial gate structures; forming epitaxial layers in the recess region; forming a gate structure by removing the sacrificial gate structures and selectively removing the sacrificial layers with respect to the plurality of semiconductor layers; and forming source/drain regions on at least a portion of the epitaxial layers through an ion implantation process. The ion implantation process uses a first ion implantation energy in the first region and a second ion implantation energy in the second region that differs from the first ion implantation energy. The source/drain regions have a first depth in the vertical direction in the first region, and have a second depth in the vertical direction in the second region that differs from the first depth.

### BRIEF DESCRIPTION OF THE DRAWINGS

FIG. 1 is a plan diagram of a semiconductor device according to an embodiment of the present disclosure.

FIG. 2 shows cross-sectional diagrams of a semiconductor device according to an embodiment of the present disclosure.

FIG. 3 shows cross-sectional diagrams of a semiconductor device according to an embodiment of the present disclosure.

FIG. 4 shows cross-sectional diagrams of a semiconductor device according to an embodiment of the present disclosure.

FIG. 5A shows cross-sectional diagrams of a semiconductor device according to an embodiment of the present disclosure.

FIG. 5B is a graph of a boundary between a source/drain region and an epitaxial layer as a function of ion implantation energy in a semiconductor device according to an embodiment of the present disclosure.

FIG. 5C is a graph of current per unit length of a plurality of semiconductor layers as a function of ion implantation energy in a semiconductor device according to an embodiment of the present disclosure.

FIG. 6 shows cross-sectional diagrams of a semiconductor device according to an embodiment of the present disclosure.

FIG. 7 shows cross-sectional diagrams of a semiconductor device according to an embodiment of the present disclosure.

FIG. 8A shows cross-sectional diagrams of a semiconductor device according to an embodiment of the present disclosure.

FIG. 8B shows cross-sectional diagrams of a semiconductor device according to an embodiment of the present disclosure.

FIG. 8C shows cross-sectional diagrams of a semiconductor device according to an embodiment of the present disclosure.

FIG. 9 shows cross-sectional diagrams of a semiconductor device according to an embodiment of the present disclosure.

FIG. 10A is a plan diagram of a semiconductor device according to an embodiment of the present disclosure.

FIG. 10B shows cross-sectional diagrams of a semiconductor device according to an embodiment of the present disclosure.

FIG. 11 shows cross-sectional diagrams of a semiconductor device according to an embodiment of the present disclosure.

FIG. 12 is a flowchart of a method of manufacturing a semiconductor device according to an embodiment of the present disclosure.

FIGS. 13A to 13H are cross-sectional diagrams that illustrate a method of manufacturing a semiconductor device according to an embodiment of the present disclosure.

FIGS. 14A and 14B are cross-sectional diagrams that illustrate a method of manufacturing a semiconductor device according to an embodiment of the present disclosure.

### DETAILED DESCRIPTION

Hereinafter, embodiments are described as follows with reference to the accompanying drawings. In the specification, when a component is described as being in contact with another component, it will be understood that the component is in direct contact with the another component.

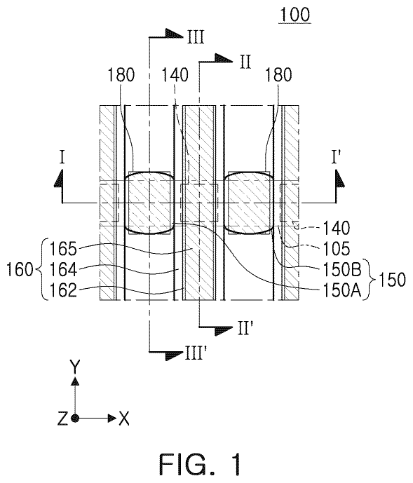

FIG. 1 is a plan diagram of a semiconductor device according to an embodiment.

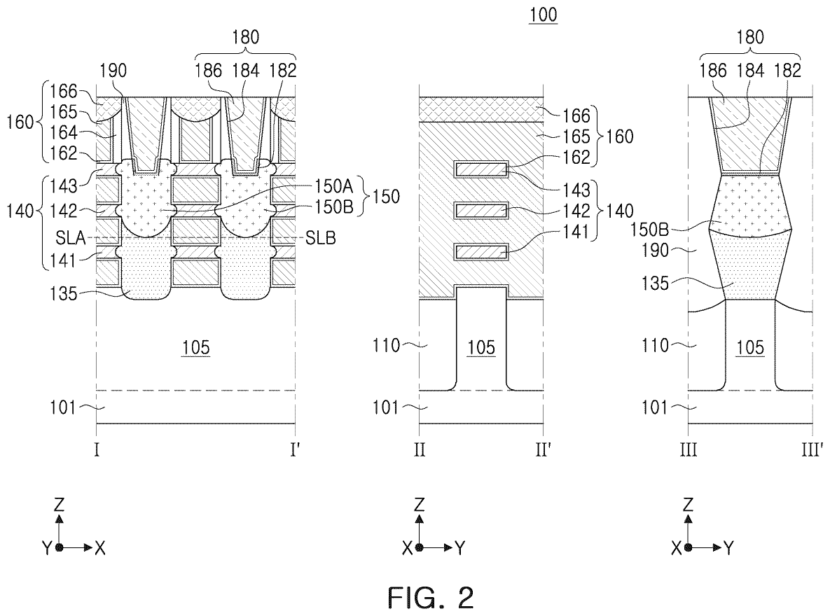

FIG. 2 shows cross-sectional diagrams of a semiconductor device according to an embodiment, taken long lines I-I′, II-II′, and III-III′ in FIG. 1.

Referring to FIGS. 1 and 2, in an embodiment, a semiconductor device 100 includes a substrate 101, an active region 105 disposed on the substrate 101, a semiconductor structure 140 that includes a plurality of semiconductor layers 141, 142, and 143 vertically disposed and spaced apart from each other on the active region 105, a gate structure 160 that crosses the active region 105, a source/drain region 150 in contact with the plurality of semiconductor layers 141, 142, and 143, and a contact structure 180 connected to the source/drain region 150. The semiconductor device 100 further includes device isolation layers 110 and an interlayer insulating layer 190. The gate structure 160 includes gate spacer layers 164, a gate dielectric layer 162, a gate electrode 165, and a gate capping layer 166.

In the semiconductor device 100, the active region 105 has a fin structure, and the gate electrode 165 is located between the active region 105 and the semiconductor structure 140, between the plurality of semiconductor layers 141, 142, and 143 of the semiconductor structures 140, and on the semiconductor structure 140. Accordingly, the semiconductor device 100 includes at least a portion of the semiconductor structure 140, a gate-all-around type field effect transistor that includes the source/drain region 150 and the gate structure 160, such as a multibridge channel FET (MBCFET™). The transistors may be, for example, NMOS transistors.

The substrate 101 has an upper surface that extends in an X-direction and a Y-direction that crosses the X direction. The substrate 101 includes a semiconductor material, such at least one of as a group IV semiconductor, a group III-V compound semiconductor, or a group II-VI compound semiconductor. For example, the group IV semiconductor includes one of silicon, germanium, or silicon-germanium. The substrate 101 is provided as one of a bulk wafer, an epitaxial layer, a silicon on insulator (SOI) layer, or a semiconductor on insulator (SeOI) layer.

The device isolation layer 110 defines the active region 105 in the substrate 101. The device isolation layer 110 is formed by, for example, a shallow trench isolation (STI) process. In embodiments, the device isolation layer 110 further includes a region that extends deeper and has a step difference below the substrate 101. The device isolation layer 110 partially exposes an upper portion of the active region 105. In embodiments, the device isolation layer 110 has a wavy upper surface whose level increases toward the active region 105. The device isolation layer 110 is formed of an insulating material. The device isolation layer 110 includes, for example, one of an oxide, a nitride, or a combination thereof.

The active region 105 is defined by the device isolation layer 110 in the substrate 101 and extends in a first direction, such as the X-direction. The active region 105 protrudes from the substrate 101. An upper end of the active region 105 protrudes from an upper surface of the device isolation layer 110 to a predetermined height. The active region 105 may be formed by a portion of the substrate 101 or may include an epitaxial layer grown from the substrate 101. However, the active region 105 on the substrate 101 is partially recessed on both sides of the gate structure 160, and the source/drain region 150 is disposed on the recessed active region 105. The active region 105 includes impurities or doped regions that include impurities.

The semiconductor structure 140 includes first to third semiconductor layers 141, 142 and 143 disposed on the active region 105 and that are spaced apart from each other in a direction perpendicular to an upper surface of the active region 105, such as a Z-direction. In an embodiment, the first semiconductor layer 141 is a lowermost semiconductor layer 141, the second semiconductor layer 142 is a second-lowermost semiconductor layer 142 adjacent to the first semiconductor layer 141, and the third semiconductor layer 143 is an uppermost semiconductor layer 143. The first to third semiconductor layers 141, 142, and 143 are connected to the source/drain region 150 and are spaced apart from the upper surface of the active region 105. The first to third semiconductor layers 141, 142, and 143 have the same or similar widths as the active region 105 in the Y-direction, and have the same or similar widths as the gate structure 160 in the X-direction. However, in some embodiments, the first to third semiconductor layers 141, 142, and 143 have a reduced width such that side surfaces are disposed below the gate structure 160 in the Z-direction. Accordingly, an area in contact with the source/drain region 150 and the plurality of semiconductor layers 141, 142, and 143 is reduced.

The first to third semiconductor layers 141, 142, and 143 are formed of a semiconductor material, and may include, for example, silicon (Si). For example, the first to third semiconductor layers 141, 142, and 143 are formed of the same material as the substrate 101. The number of the plurality of semiconductor layers 141, 142, and 143 included in one semiconductor structure 140 and the shapes thereof may vary in other embodiments. For example, in some embodiments, the semiconductor structure 140 further includes semiconductor layers disposed on an upper surface of active region 105. In an embodiment, the first semiconductor layer 141 does not substantially function as a channel region of a transistor.

The gate structure 160 is disposed across the active region 105 and the semiconductor structures 140 on the active region 105, and extends in one direction, such as the Y-direction. A channel region of transistors is formed in the active region 105 and the semiconductor structures 140 that cross the gate structure 160. The gate structure 160 includes a gate electrode 165, a gate dielectric layer 162 between the gate electrode 165 and the plurality of semiconductor layers 141, 142, and 143, gate spacer layers 164 on the side surfaces of the gate electrode 165, and a gate capping layer 165 on the upper surface of the gate electrode 165.

The gate dielectric layer 162 is disposed between the active region 105 and the gate electrode 165 and between the semiconductor structure 140 and the gate electrode 165, and covers at least a portion of the surfaces of the gate electrode 165. For example, the gate dielectric layer 162 surrounds all surfaces of the gate electrode 165 other than the uppermost surface of the gate electrode 165. The gate dielectric layer 162 extends to a region between the gate electrode 165 and the gate spacer layers 164, but an embodiment thereof is not necessarily limited thereto. The gate dielectric layer 162 may include two or more multiple layers. The gate dielectric layer 162 includes at least one of an oxide, a nitride, or a high-K material. The high-K material is a dielectric material that has a higher dielectric constant than silicon oxide (SiO₂). The high-K material is one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The gate electrode 165 fills a region between the plurality of semiconductor layers 141, 142, and 143 on the active region 105 and extends into a region above the plurality of semiconductor layers 141, 142, and 143. The gate electrode 165 is spaced apart from the plurality of semiconductor layers 141, 142, and 143 by the gate dielectric layer 162. The gate electrode 165 includes a conductive material, such a metal nitride such as titanium nitride (TiN), tantalum nitride (TaN), or tungsten nitride (WN), and/or a metal such as aluminum (Al), tungsten (W), or molybdenum (Mo), or a semiconductor material such as doped polysilicon.

The gate electrode 165 includes two or more multiple layers. The gate spacer layers 164 are disposed on both side surfaces of gate electrode 165. The gate dielectric layer 162 is interposed between the gate electrode 165 and the gate spacer layers 164. The gate spacer layers 164 insulate the source/drain region 150 and the gate electrode 165. The gate spacer layers 164 have a multiple layer structure in some embodiments. The gate spacer layers 164 include at least one of an oxide, a nitride, oxynitride or a low-K dielectric.

The gate capping layer 166 is disposed on the gate electrode 165. The gate capping layer 166 extends in a second direction, such as a Y direction along the upper surface of the gate electrode 165. Side surfaces of the gate capping layer 166 are surrounded by the gate spacer layers 164. An upper surface of the gate capping layer 166 is substantially coplanar with an upper surface of the gate spacer layers 164, but an embodiment thereof is not necessarily limited thereto. The gate capping layer 166 includes an oxide, a nitride, or an oxynitride, such as at least one of SiO, SiN, SiCN, SiOC, SiON, or SiOCN.

The source/drain region 150 is disposed on at least one side of the gate structure 160, is in contact with at least a portion of the plurality of semiconductor layers 141, 142, and 143, and is disposed on an epitaxial layer 135 (described below) and the active region 105. The source/drain region 150 serves as a source region or a drain region of a transistor. The source/drain region 150 is disposed along side surfaces of the plurality of semiconductor layers 141, 142, and 143. The surfaces of the source/drain region 150 in contact with the plurality of semiconductor layers 141, 142, and 143 and the gate dielectric layer 162 have a rounded shape. The source/drain region 150 includes a plurality of layers, but embodiments thereof are not necessarily limited thereto. The source/drain region 150 is a semiconductor layer that includes silicon (Si) and/or germanium (SiGe). By an ion implantation process (IIP), the source/drain region 150 includes impurities of different types and/or concentrations. For example, the source/drain region 150 may include N-type doped silicon (Si) and/or P-type doped silicon germanium (SiGe). In some embodiments, the source/drain region 150 includes a plurality of regions that include different concentrations of elements and/or dopants.

In an embodiment, the source/drain regions 150 includes a first source/drain region 150A and a second source/drain region 150B respectively disposed on each side of the gate structure 160. A level SLA of a lowermost end of the first source/drain region 150A is the same as a level SLB of a lowermost end of the second source/drain region 150B, but embodiments thereof are not necessarily limited thereto. The depth of the source/drain regions 150 can be adjusted through an ion implantation process (IIP), and accordingly, of the plurality of semiconductor layers 141, 142, and 143, the second and third semiconductor layers 142 and 143 that electrically connect the first source/drain region 150A to the second source/drain region 150B are used as the channel layers. In an embodiment, the level SLA of the lowermost end of the first source/drain region 150A and the level SLB of the lowermost end of the second source/drain region 150B are lower than a level of the lower surface of the second semiconductor layer 142. The second and third semiconductor layers 142 and 143 are channel layers that electrically connect the first source/drain region 150A to the second source/drain region 150B.

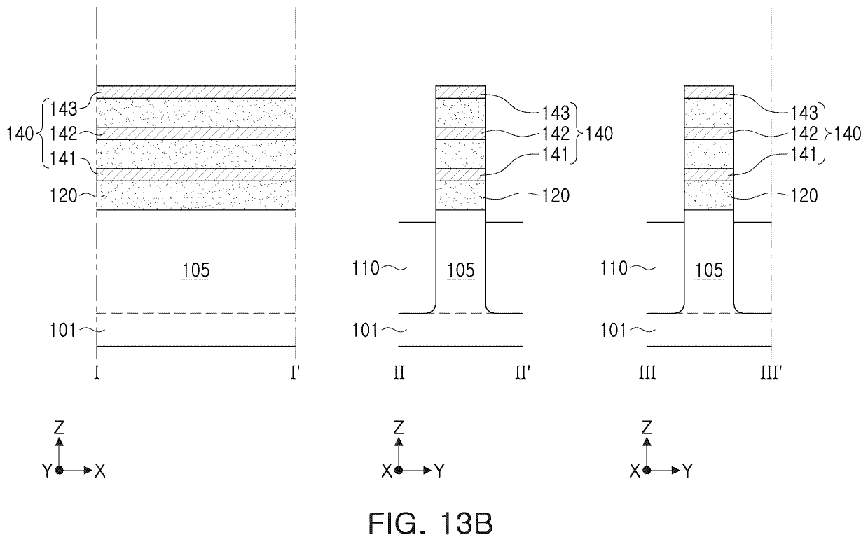

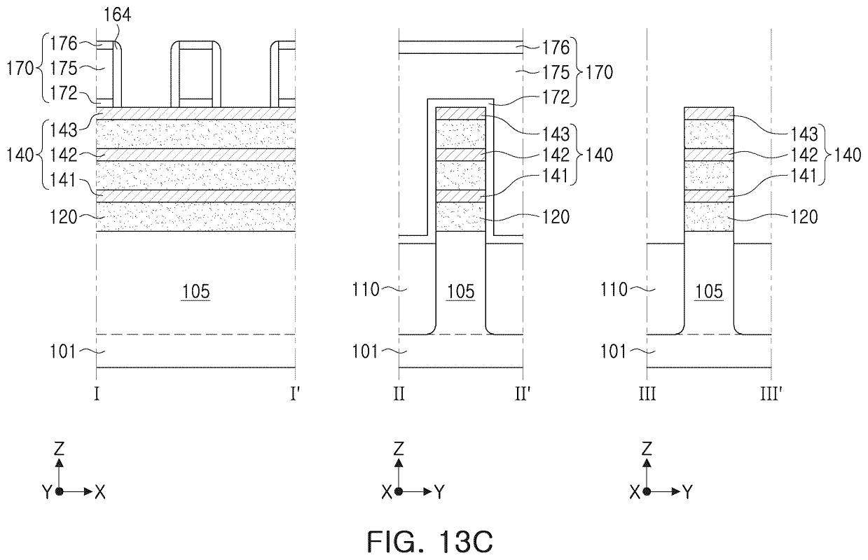

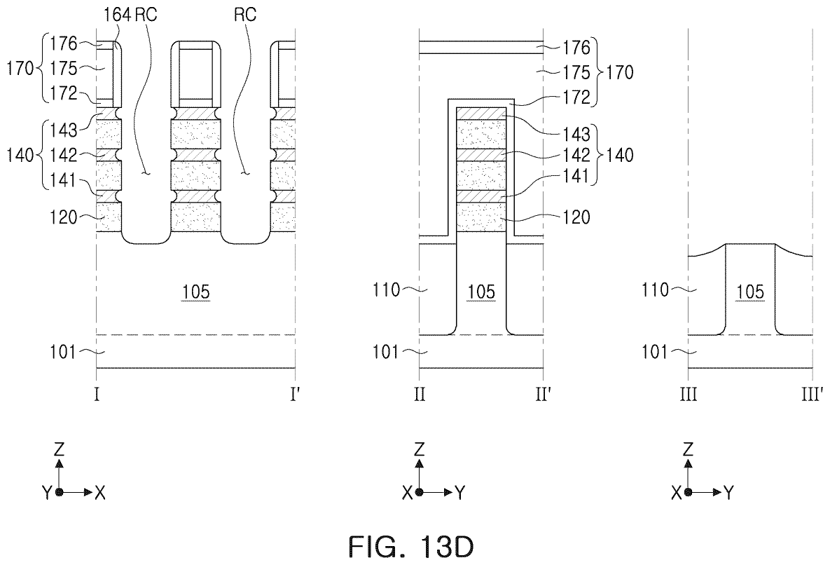

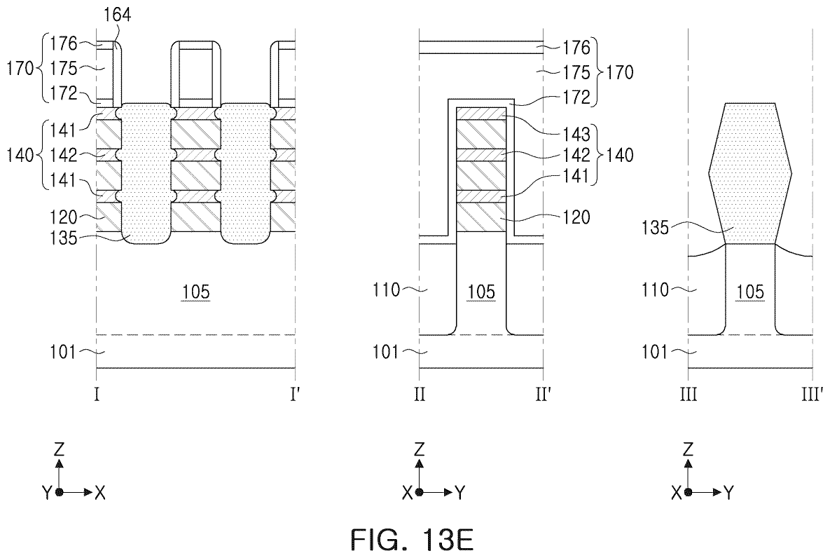

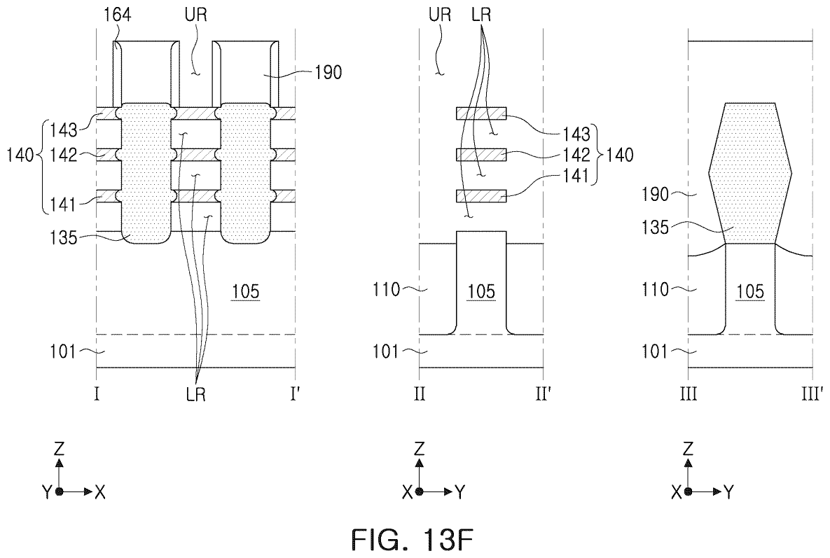

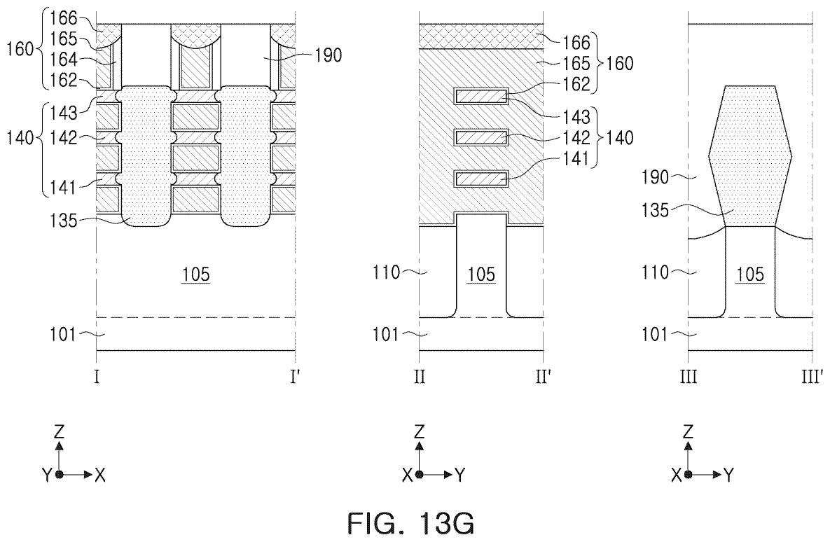

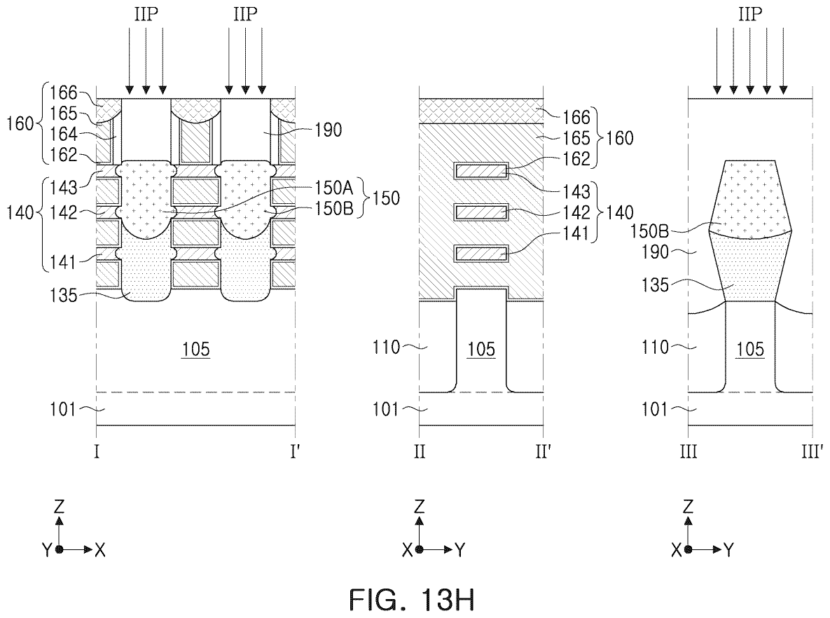

The epitaxial layer 135 is disposed between the active region 105 and the source/drain regions 150. The epitaxial layer 135 is formed by an epitaxial growth process in a process illustrated by FIG. 13E and described below. The epitaxial layer 135 includes silicon (Si) or silicon germanium (SiGe), but does not include impurities. In an embodiment, the epitaxial layer 135 is an undoped layer. Depending on conditions of the ion implantation process (IIP), the depth of the source/drain regions 150 can vary, and accordingly, regions in which the epitaxial layer 135 is in contact with the plurality of semiconductor layers 141, 142, and 143 can vary. Since the source/drain regions 150 include impurities by the ion implantation process (IIP), and the material compositions of the source/drain regions 150 and epitaxial layer 135 differ, the layer and regions can be determined by analyzing the concentration of impurities through an analysis such as transmission electron microscopy energy-dispersive X-ray spectroscopy (TEM-EDX). For example, the boundary between the source/drain regions 150 and the epitaxial layer 135 may be defined based on a concentration of impurities of about 1×10¹⁹ atoms/cm³ to about 1×10²⁰ atoms/cm³. In addition, the impurity concentration may be measured by time-of-flight secondary ion mass spectrometry (ToF-SIMS), and the boundary between the source/drain regions 150 and the epitaxial layer 135 is distinct.

In an embodiment, the epitaxial layer 135 is spaced apart from the third semiconductor layer 143, which is an uppermost semiconductor layer of the plurality of semiconductor layers 141, 142, and 143, and is disposed below the source/drain regions 150. The epitaxial layer 135 is in contact with at least a portion of side surfaces of the first semiconductor layer 141, which is the lowermost semiconductor layer of the plurality of semiconductor layers 141, 142, and 143. The epitaxial layer 135 is partially recessed into the upper portion of the active region 105, but in some embodiments, the presence or absence of the recess and the depth of the recess can vary. The surfaces of the epitaxial layer 135 in contact with the side surfaces of the first semiconductor layer 141 have a rounded shape. The lower portion of the epitaxial layer 135 has a downwardly convex shape, but embodiments thereof are not necessarily limited thereto. Since the epitaxial layer 135 is formed by an epitaxial growth process, the epitaxial layer 135 extends from an upper portion of the active region 105 to a lower portion of the source/drain regions 150. Cross-sectional surfaces of the source/drain regions 150 and the epitaxial layer 135 in the Y-direction have at least one of a pentagonal shape, a hexagonal shape, an elliptical shape, or a circular shape. However, in other embodiments, the source/drain region 150 has other shapes, such as one of a polygonal shape, a circular shape, or a rectangular shape.

External side surfaces of the source/drain regions 150 and the epitaxial layer 135 protrude toward the plurality of semiconductor layers 141, 142, and 143. Accordingly, each of the source/drain regions 150 and epitaxial layer 135 includes a protrusion that protrudes toward the plurality of semiconductor layers 141, 142, and 143 on the same level as a level of the plurality of semiconductor layers 141, 142, and 143.

The contact structures 180 penetrate through at least a portion of the interlayer insulating layer 190, are in contact with the source/drain region 150 and apply an electrical signal to the source/drain region 150. The contact structures 180 are disposed on the source/drain region 150 and, in some embodiments, the contact structures 180 are relatively longer in the Y-direction than the source/drain region 150. The contact structures 180 have inclined side surfaces, such that a width of the lower portion is narrower than a width of the upper portion, but embodiments thereof are not necessarily limited thereto. The contact structures 180 are recessed into the source/drain region 150 to a predetermined depth.

The contact structures 180 includes a first metal-semiconductor compound layer 182 disposed on a lower end, a barrier layer 184 disposed along sidewalls, and a plug conductive layer 186 that fills a space formed by the barrier layer 184. The first metal-semiconductor compound layer 182 is, for example, a metal silicide layer. The barrier layer 184 includes, for example, a metal nitride such as one of titanium nitride (TiN), tantalum nitride (TaN), or tungsten nitride (WN). The plug conductive layer 186 includes, for example, a metal such as at least one of aluminum (Al), tungsten (W), or molybdenum (Mo). In some embodiments, the contact structure 180 penetrates through at least a portion of the source/drain region 150. In other embodiments, the number of the conductive layers in the contact structures 180 and the arrangement thereof can vary. In addition, in some embodiments, a wiring structure such as a contact structure is further disposed on the gate electrode 165, and a wiring structure connected to the contact structures 180 is further disposed on the contact structures 180.

The interlayer insulating layer 190 covers the source/drain region 150, the gate structure 160 and the device isolation layer 110. The interlayer insulating layer 190 includes, for example, at least one of an oxide, a nitride, oxynitride, or a low-K dielectric.

In the description of embodiments below, descriptions of components described above with reference to FIGS. 1 and 2 may be summarized or omitted.

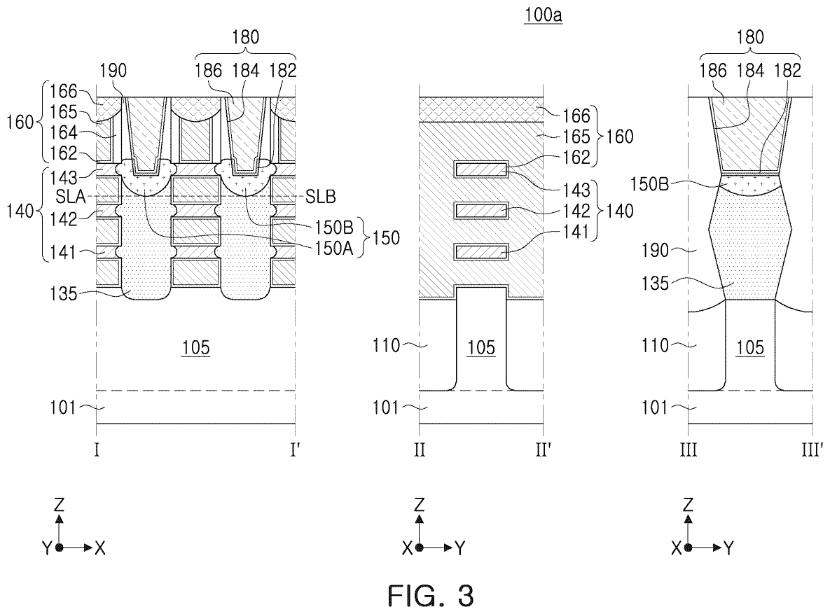

FIG. 3 shows cross-sectional diagrams of a semiconductor device according to an embodiment that illustrate cross-sectional surfaces that correspond to the cross-sectional surfaces taken long lines I-I′, II-II′, and III-III′ shown in FIG. 2.

Referring to FIG. 3, in an embodiment, a level of a lowermost end of each of the source/drain regions 150 may be lower than a level of a lower surface of the third semiconductor layer 143. In an embodiment, a level SLA of the lowermost end of the first source/drain region 150A is lower than a level of the lower surface of the third semiconductor layer 143 and higher than a level of an upper surface of the second semiconductor layer 142, and a level SLB of a lowermost end of the second source/drain region 150B is lower than a level of a lower surface of the third semiconductor layer 143 and higher than a level of an upper surface of the second semiconductor layer 142. Accordingly, the first source/drain region 150A and the second source/drain region 150B are electrically connected to each other by the third semiconductor layer 143. The third semiconductor layer 143 is used as a channel layer. The level SLA of the lowermost end of the first source/drain region 150A is the same as the level SLB of the lowermost end of the second source/drain region 150B, but embodiments thereof are not necessarily limited thereto. The epitaxial layer 135 is in contact with at least a portion of side surfaces of the lowermost semiconductor layer 141 and the second-lowermost semiconductor layer 142 adjacent thereto.

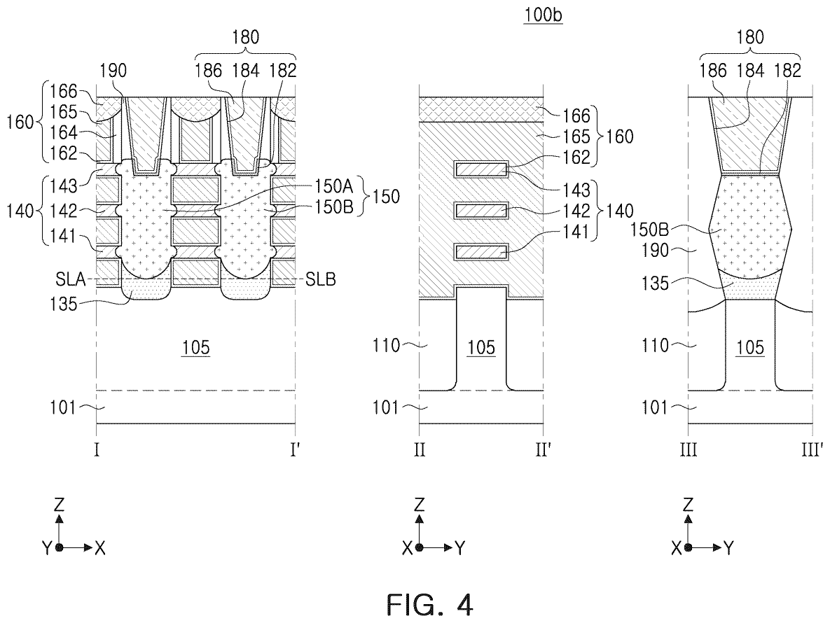

FIG. 4 shows cross-sectional diagrams of a semiconductor device according to an embodiment that illustrate cross-sectional surfaces that correspond to the cross-sectional surfaces taken long lines I-I′, II-II′, and III-III′ shown in FIG. 2.

Referring to FIG. 4, in an embodiment, a level of a lowermost end of each of the source/drain regions 150 is lower than a level of a lower surface of the first semiconductor layer 141. In an embodiment, a level SLA of a lowermost end of the first source/drain region 150A is lower than a level of a lower surface of the first semiconductor layer 141, and a level SLB of a lowermost end of the second source/drain region 150B is lower than a level of a lower surface of the first semiconductor layer 141. Accordingly, the first source/drain region 150A and the second source/drain region 150B are electrically connected to each other by the first to third semiconductor layers 141, 142, and 143. The first to third semiconductor layers 141, 142, and 143 are used as a channel layer. The level SLA of the lowermost end of the first source/drain region 150A is the same as the level SLB of the lowermost end of the second source/drain region 150B, but embodiments thereof are not necessarily limited thereto.

In FIG. 4, the epitaxial layer 135 is shown as being present between the source/drain regions 150 and the active region 105, but in a process shown in FIG. 13H, depending on the conditions of the ion implantation process (IIP), the entirety of the epitaxial layer 135 may be formed as the source/drain regions 150.

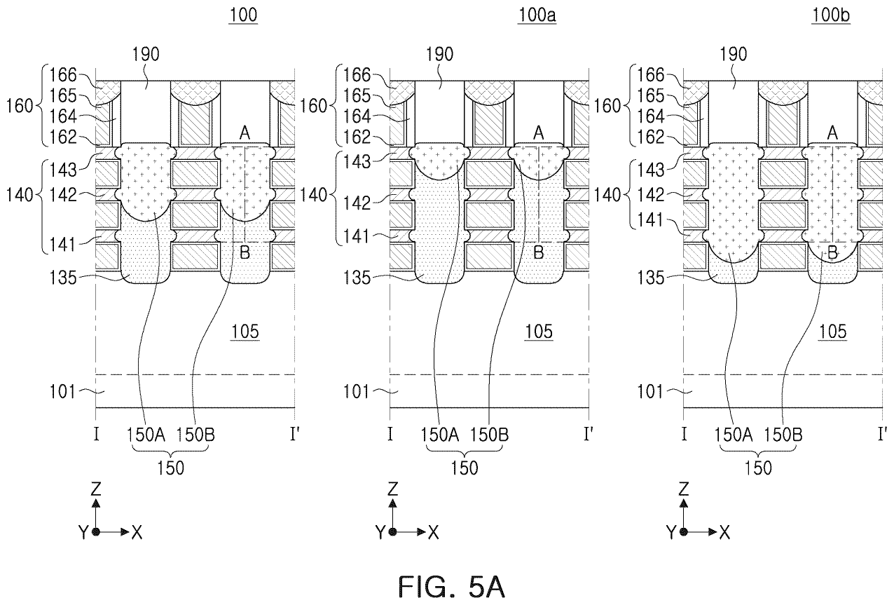

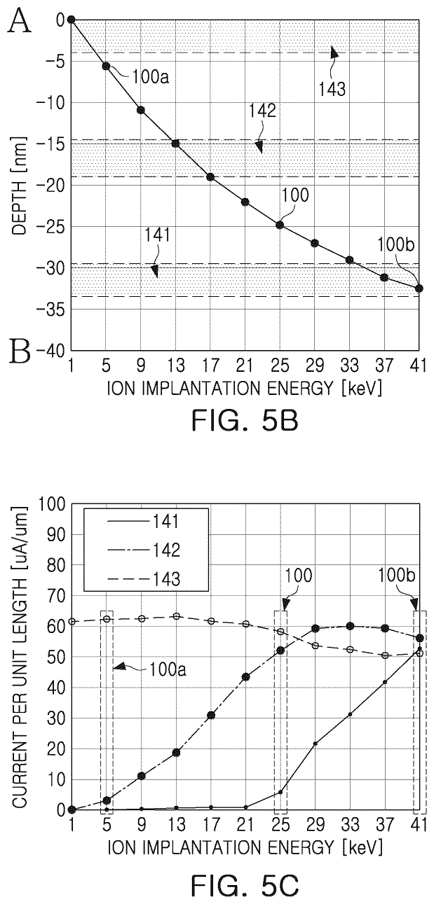

FIG. 5A shows cross-sectional diagrams of a semiconductor device taken along line I-I′ in FIG. 1, according to an embodiment. FIG. 5A illustrates processes before forming the contact structure 180 of the semiconductor device 100 in FIG. 2, before forming the contact structure 180 of the semiconductor device 100A in FIG. 3 and before forming the contact structure 180 of the semiconductor device 100B in FIG. 4.

FIG. 5B is a graph of a boundary between a source/drain region and an epitaxial layer as a function of ion implantation energy in a semiconductor device in some embodiments. The horizontal axis of the graph in FIG. 5B indicates the magnitude of ion implantation energy, and the vertical axis indicates the depth of the boundary along a line from A to B in FIG. 5A. FIG. 5B illustrates the depths of the plurality of semiconductor layers 141, 142, and 143, and illustrates that the boundary between the source/drain region 150 and the epitaxial layer 135 depend on the magnitude of ion implantation energy.

FIG. 5C is a graph of current per unit length of a plurality of semiconductor layers according to an ion implantation energy in a semiconductor device in some embodiments. The horizontal axis of the graph in FIG. 5C indicate the magnitude of ion implantation energy, and the vertical axis indicates the current per unit length of the plurality of semiconductor layers 141, 142, and 143.

Referring to FIGS. 5A to 5C, FIG. 5B is a graph that represents the depth of the source/drain regions 150, such as the boundary between the source/drain regions 150 and the epitaxial layer 135, as a function of the magnitude of ion implantation energy, and FIG. 5C is a graph that represents the current per unit length of the plurality of semiconductor layers 141, 142, and 143 as a function of the magnitude of ion implantation energy. The lengths of the plurality of semiconductor layers 141, 142, and 143 are lengths in the Y-direction in FIG. 5A.

In FIG. 5A, A-B is a line along a central axis of each of the source/drain regions 150. For example, A-B is a line that vertically overlaps a lowermost end of each of the source/drain regions 150. A level of A corresponds to an upper surface of the third semiconductor layer 143, and a level of B corresponds to a lower surface of the first semiconductor layer 141. The embodiments are shown together with each other, and FIG. 5A illustrates the semiconductor devices 100, 100a, and 100B in FIGS. 2 to 4.

As illustrated in FIG. 5B, as the magnitude of ion implantation energy increases, the depth of the source/drain regions 150, that is, the boundary between the source/drain regions 150 and the epitaxial layer 135 shifts to a deeper depth.

In an embodiment, in the semiconductor device 100A in FIG. 3, the source/drain regions 150 are formed with an ion implantation energy of about 5 keV. The lowermost end of the boundary between the source/drain regions 150 and the epitaxial layer 135 is located at a level lower than a level of the lower surface of the third semiconductor layer 143. As illustrated in FIG. 5C, when the source/drain regions 150 are formed with an ion implantation energy of about 5 keV, in the third semiconductor layer 143, current per unit length ranges from about 60 μA/μm to about 65 μA/μm. For example, the third semiconductor layer 143 is used as a channel layer. The ion implantation energy magnitude for using the third semiconductor layer 143 as a channel layer is not limited to about 5 keV, and the ion implantation energy magnitude can range from about 1 keV to about 10 keV, depending on the semiconductor devices.

In an embodiment, in the semiconductor device 100 in FIG. 2, the source/drain regions 150 are formed with an ion implantation energy of about 25 keV. The lowermost end of the boundary between the source/drain regions 150 and the epitaxial layer 135 is located at a level lower than a level of the lower surface of the second semiconductor layer 142. As shown in FIG. 5C, when the source/drain regions 150 are formed with an ion implantation energy of about 25 keV, the current per unit length in the second and third semiconductor layers 142 and 143 ranges from about 50 μA/μm to about 60 μA/μm. For example, the second and third semiconductor layers 142 and 143 are used as a channel layer. The ion implantation energy magnitude for using the second and third semiconductor layers 142 and 143 as the channel layer is not limited to about 25 keV, and depending on the semiconductor device, the ion implantation energy magnitude can range from about 15 keV to about 30 keV.

In an embodiment, in the semiconductor device 100B in FIG. 4, the source/drain regions 150 is formed with an ion implantation energy of about 41 keV. The lowermost end of the boundary between the source/drain regions 150 and the epitaxial layer 135 is located at a level lower than a level of the lower surface of the second semiconductor layer 142. As shown in FIG. 5C, when the source/drain regions 150 are formed with an ion implantation energy of about 41 keV, the current per unit length ranges from about 50 μA/μm to about 60 μA/μm in the first to third semiconductor layers 141, 142, and 143. For example, the first to third semiconductor layers 141, 142, and 143 are used as a channel layer. The ion implantation energy magnitude for using the first to third semiconductor layers 141, 142, and 143 as the channel layer is not limited to about 41 keV, and the ion implantation energy magnitude can be about 35 keV or more, depending on the semiconductor device.

In an embodiment, by adjusting the depth of the source/drain regions 150 by the ion implantation energy magnitude, a plurality of semiconductor layers 141, 142, and 143 that electrically connect the source/drain regions 150 to each other can be selected from the plurality of semiconductor layers 141, 142, and 143. Accordingly, as shown in FIGS. 5A to 5C, the numerical values of the ion implantation energy magnitude, the depth of the source/drain regions 150, the current per unit length of the plurality of semiconductor layers 141, 142, and 143, and the depth of the plurality of semiconductor layers 141, 142, and 143, are not limited to the above-mentioned numerical values and can vary in semiconductor devices according to other embodiments.

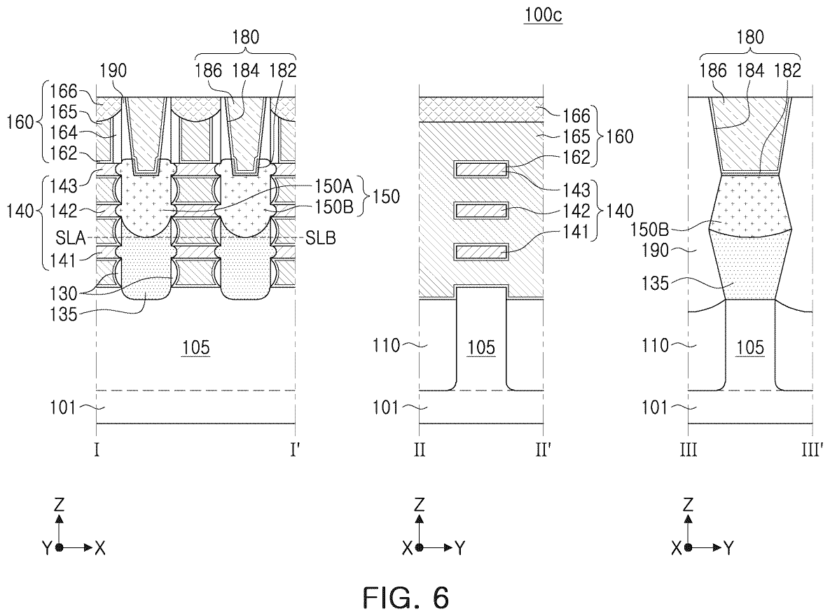

FIG. 6 shows cross-sectional diagrams of a semiconductor device according to an embodiment that illustrate cross-sectional surfaces that correspond to the cross-sectional surfaces taken long lines I-I′, II-II′, and III-III′ and as shown in FIG. 2.

Referring to FIG. 6, in an embodiment, the semiconductor device 100c further includes internal spacer layers 130 disposed on both sides of the gate structure 160 in the first direction X on side surfaces of each of the plurality of semiconductor layers 141, 142, and 143, different from the semiconductor device 100 in FIG. 2. The internal spacer layers 130 are in contact with the gate dielectric layer 162. The internal spacer layers 130 are disposed between the gate structure 160 and the source/drain regions 150, and between the gate structure 160 and the epitaxial layer 135. The side surfaces of the internal spacer layers 130 are in contact with the source/drain region 150 and the epitaxial layer 135. Below each of the plurality of semiconductor layers 141, 142, and 143, the gate electrodes 165 are spaced apart from the source/drain region 150 by the internal spacer layers 130 and are electrically isolated from each other. Side surfaces of the internal spacer layers 130 that oppose the gate electrode 165 have an inwardly curved and rounded shape that is curved toward the gate electrode 165. The internal spacer layers 130 are formed of at least one of an oxide, a nitride, an oxynitride, or a low-K film.

The internal spacer layers 130 is formed of the same material as the gate spacer layers 164, but embodiments thereof are not necessarily limited thereto. For example, the internal spacer layers 130 include at least one of SiN, SiCN, SiOCN, SiBCN, or SiBN. The internal spacer layers 130 can also be applied to embodiments shown in FIGS. 3 and 4.

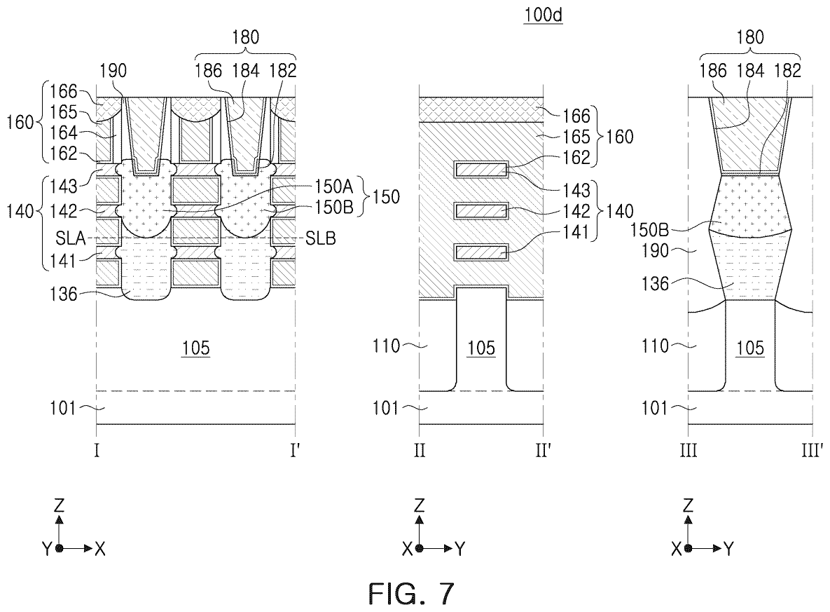

FIG. 7 shows cross-sectional diagrams of a semiconductor device according to an embodiment that illustrate cross-sectional surfaces that correspond to the cross-sectional surfaces taken long lines I-I′, II-II′, and III-III′ and as shown in FIG. 2.

Referring to FIG. 7, in an embodiment, in the semiconductor device 100d, impurities in the epitaxial layer 135 have conductivity-types that differ from the conductivity-types of impurities in the source/drain regions 150. For example, the epitaxial layer 135 may be referred to as a counter layer 136. The source/drain regions 150 and the counter layer 136 include elements from different groups of the periodic table of elements. In an embodiment, the source/drain regions 150 includes first impurities that include at least one of a group 13 element or a group 15 element of the periodic table of elements, and the counter layer 136 includes second impurities that include another element of the group 13 elements or the group 15 elements. For example, the counter layer 136 includes at least one of boron (B), aluminum (Al), gallium (Ga), indium (In), or thallium (Tl), which are P-type impurities. The source/drain regions 150 include at least one of phosphorus (P), arsenic (As), or antimony (Sb), which are N-type impurities. However, embodiments thereof are not necessarily limited thereto, and in other embodiments, the counter layer 136 includes N-type impurities and the source/drain regions 150 include P-type impurities.

In another embodiment, the counter layer 136 further includes the first impurities. A concentration of the first impurities in the source/drain regions 150 is higher than a concentration of the first impurities in the epitaxial layer 135. The epitaxial layer 135 and the counter layer 136 include the first impurities due to thermal diffusion, but an embodiment thereof is not necessarily limited thereto.

In another embodiment, the source/drain regions 150 further include the second impurities. A concentration of the second impurities in the counter layer 136 is higher than a concentration of the second impurities in the source/drain regions 150. The source/drain regions 150 include the second impurities due to thermal diffusion, but an embodiment thereof is not necessarily limited thereto.

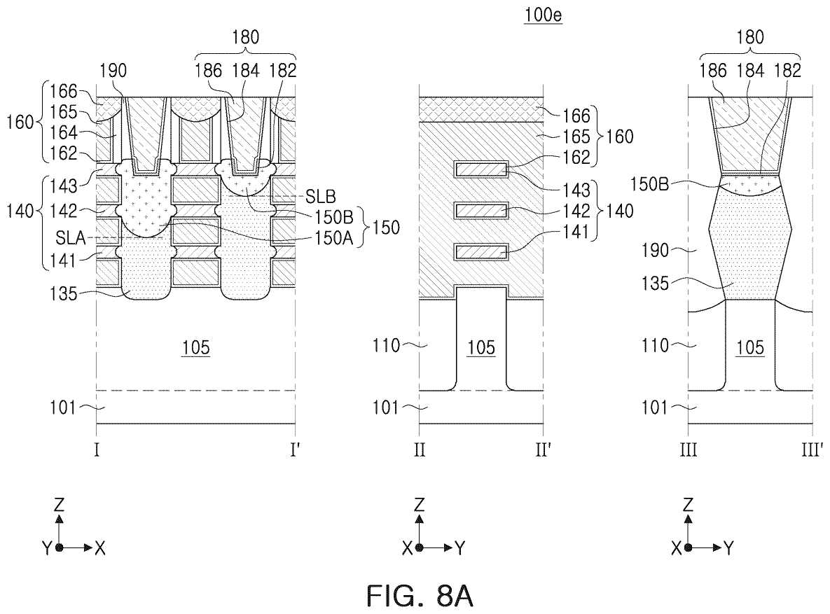

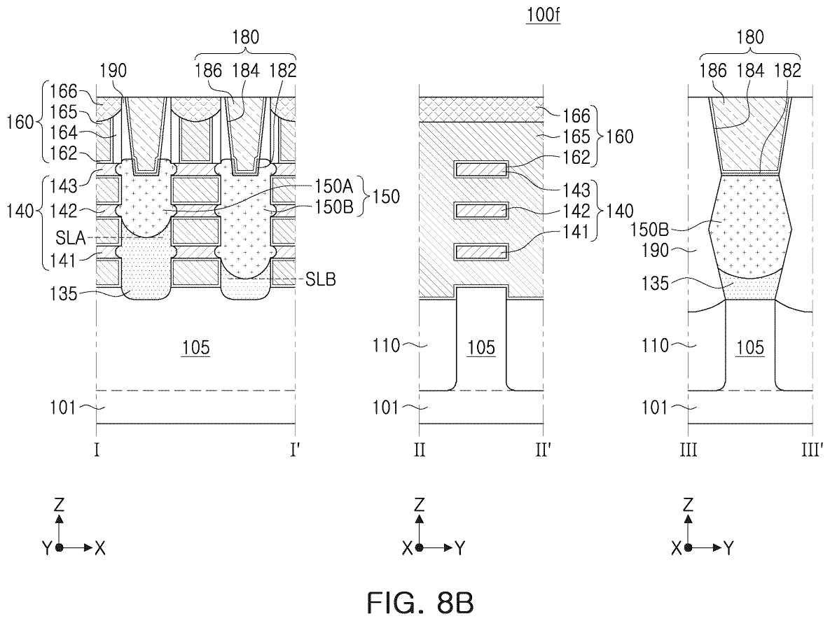

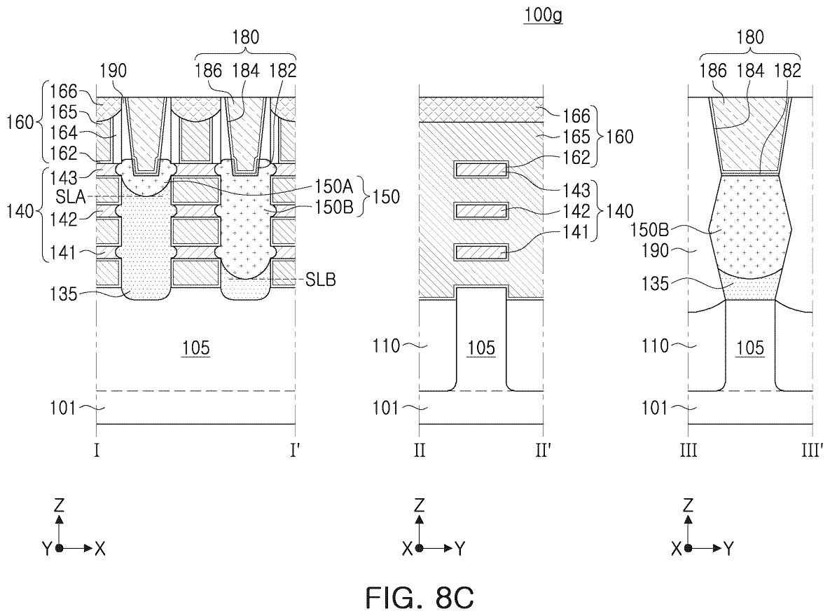

FIGS. 8A to 8C show cross-sectional diagrams of a semiconductor device according to an embodiment.

FIGS. 8A to 8C illustrate cross-sectional surfaces that correspond to the cross-sectional surfaces taken along lines I-I′, II-II′, and III-III′ and as shown in FIG. 2.

Referring to FIGS. 8A to 8C, in some embodiments, in the semiconductor devices 100e, 100f, and 100g, the levels of the lowermost ends of the source/drain regions 150 on each side of the gate structure 160 differ. In an embodiment, the level SLA of the lowermost end of the first source/drain region 150A differs from the level SLB of the lowermost end of the second source/drain region 150B, which is due to different depths of the source/drain regions 150 due to varying the conditions of the ion implantation process (IIP) illustrated in FIG. 13H and described below.

The first source/drain region 150A and the second source/drain region 150B are electrically connected to each other by those semiconductor layers 141, 142, and 143 that are disposed on a level higher than the highest of the level SLA of the first source/drain region 150A and the level SLB of the second source/drain region 150B. As illustrated in FIG. 8A, in an embodiment, since the level SLB of the second source/drain region 150B is higher than the level SLA of the first source/drain region 150A and the uppermost surface of the second semiconductor layer 142, the source/drain regions are electrically connected to each other by the third semiconductor layer 143 disposed higher than the above levels. For example, the third semiconductor layer 143 is used as a channel layer.

As illustrated in FIG. 8B, in an embodiment, since the level SLA of the first source/drain region 150A is higher than the level SLB of the second source/drain region 150B and the uppermost surface of the first semiconductor layer 141, the source/drain regions are electrically connected to each other by the second and third semiconductor layers 142 and 143 disposed higher than the above levels. For example, the second and third semiconductor layers 142 and 143 are used as channel layers.

As illustrated in FIG. 8C, in an embodiment, since the level SLA of the first source/drain region 150A is higher than the level SLB of the second source/drain region 150B and the uppermost surface of the second semiconductor layer 142, the source/drain regions are electrically connected to each other by the third semiconductor layer 143 disposed higher than the above levels. For example, the third semiconductor layer 143 is used as a channel layer.

As above, in the process illustrated in FIG. 13H, by varying the depth of the source/drain regions 150, the plurality of semiconductor layers 141, 142, and 143 can be selectively used as a channel layer.

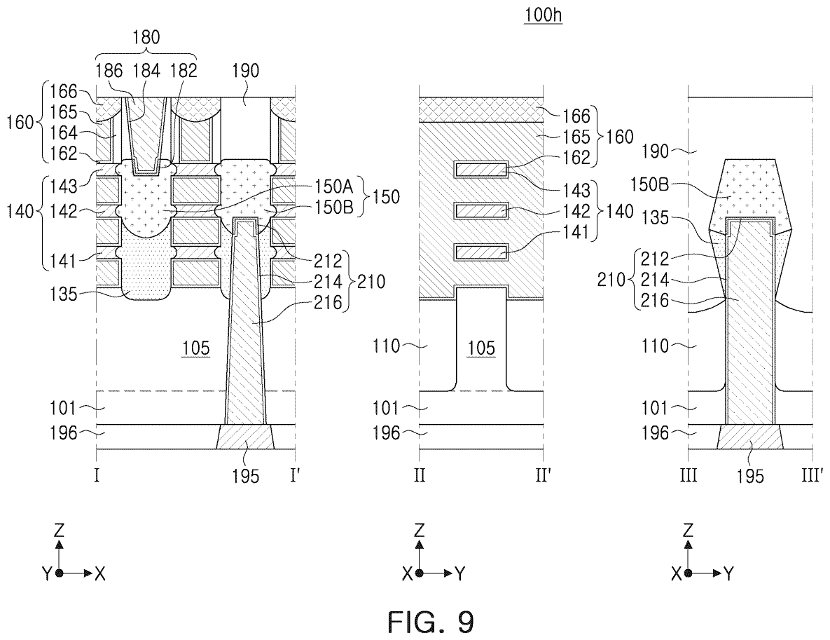

FIG. 9 shows cross-sectional diagrams of a semiconductor device according to an embodiment that illustrate cross-sectional surfaces that corresponding to the cross-sectional surfaces taken long lines I-I′, II-II′, and III-III′ and as shown in FIG. 2.

Referring to FIG. 9, in an embodiment, the semiconductor device 100h further includes a backside contact structure 210 connected to a lower portion of the second source/drain region 150B. In an embodiment, no contact structure 180 connected to an upper portion of the second source/drain region 150B is provided.

The backside contact structure 210 extends vertically and penetrates through the substrate 101, the active region 105, and the epitaxial layer 135. In an embodiment, the backside contact structure 210 penetrates through the epitaxial layer 135, and is electrically connected to the second source/drain region 150B. The backside contact structure 210 is partially recessed into a lower region of the second source/drain region 150B, and is in contact with the recessed lower surface of the second source/drain region 150B. The backside contact structure 210 has a width that decreases with increasing distance from the lower surface of the substrate 101 toward the second source/drain region 150B, but an embodiment thereof is not necessarily limited thereto. In another embodiment, in a process of forming the backside contact structure 210, both the substrate 101 and the active region 105 are removed, such that the lower insulating layer 196 covers the lower portions of the gate structure 160 and the epitaxial layer 135.

The backside contact structure 210 includes a liner layer 214, a second metal-semiconductor compound layer 212, and a conductive layer 216. The liner layer 214 forms external side surfaces of the backside contact structure 210 and forms a portion of an upper surface of the backside contact structure 210. However, the range of extension of the liner layer 214 can vary in other embodiments. The liner layer 214 includes, for example, a metal nitride layer such as at least one of titanium nitride (TiN), tantalum nitride (TaN), or tungsten nitride (WN).

The second metal-semiconductor compound layer 212 is disposed on an upper end of the backside contact structure 210 and the liner layer 214 and forms at least a portion of the upper surface of the backside contact structure 210. The second metal-semiconductor compound layer 212 is disposed on a surface of the backside contact structure 210 that is in contact with the second source/drain region 150B. However, in other embodiments, the range of the second metal-semiconductor compound layer 212 is not limited to the illustrated example. The second metal-semiconductor compound layer 212 is, for example, a metal silicide layer. A conductive layer 216 is disposed that fills a contact hole surrounded by the liner layer 214 and the second metal-semiconductor compound layer 212. The conductive layer 216 includes, for example, a metal such as at least one of aluminum (Al), tungsten (W), or molybdenum (Mo). In other embodiments, the number of the conductive layers in the backside contact structure 210 and the arrangement thereof can vary. In some embodiments, the liner layer 214 and/or the second metal-semiconductor compound layer 212 are omitted.

The second source/drain region 150B is electrically connected to a backside power structure 195 through the backside contact structure 210 and receives power therefrom.

The backside power structure 195 is connected to a lower end or a lower surface of the backside contact structure 210. The backside power structure 195, together with the backside contact structure 210, form a BSPDN (BackSide Power Delivery Network) that applies power or a ground voltage, and may also be referred to as a rear power rail or a buried power rail. For example, the backside power structure 195 is a buried wiring line that extends from below the backside contact structure 210 in one direction, such as the Y-direction, but the shape of the backside power structure 195 is not necessarily limited thereto. For example, in some embodiments, the backside power structure 195 includes via regions and/or line regions. The width of the backside power structure 195 may be constant, but an embodiment thereof is not necessarily limited thereto, and in another embodiment, the width continuously increases. The backside power structure 195 includes a conductive material, such as at least one of tungsten (W), copper (Cu), aluminum (Al), cobalt (Co), ruthenium (Ru), titanium (Ti), or molybdenum (Mo).

The lower insulating layer 196 includes at least one of an oxide, a nitride, or an oxynitride, and includes, for example, a low dielectric constant material. In some embodiments, the lower insulating layer 196 includes a plurality of insulating layers.

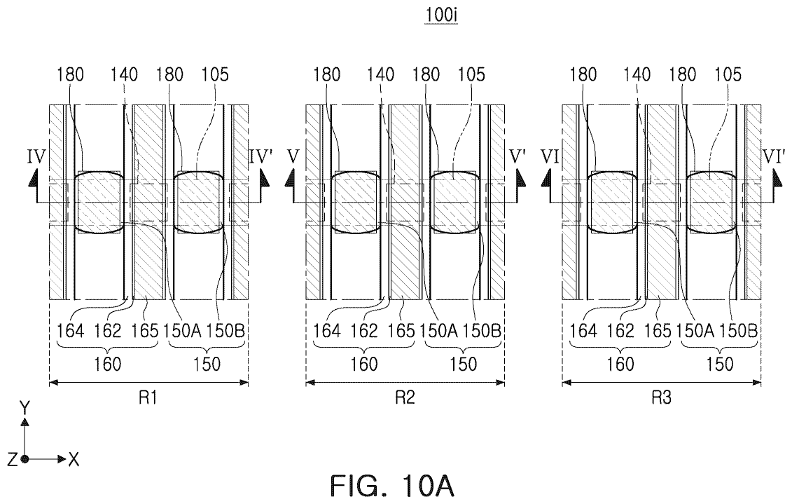

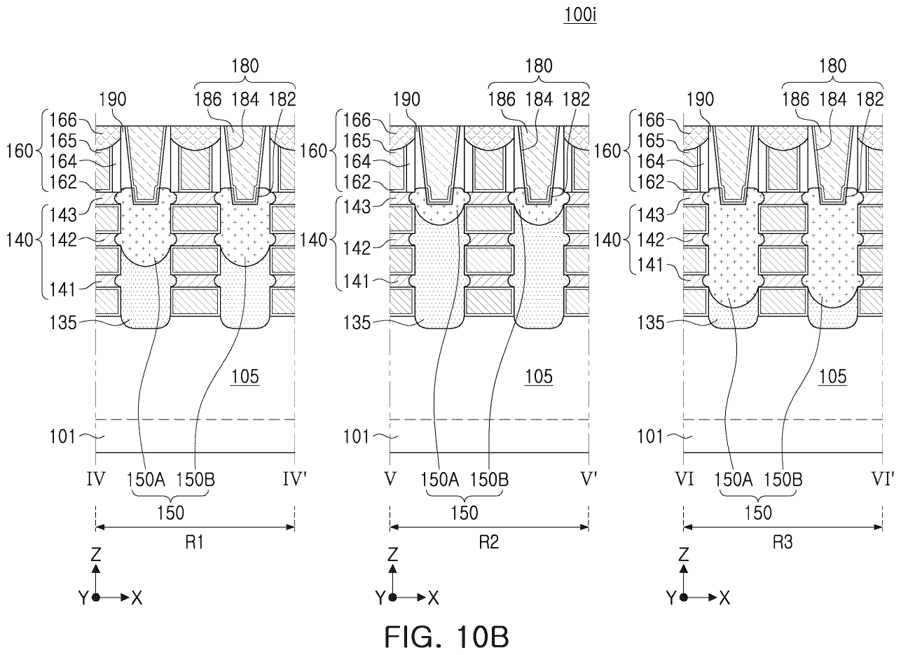

FIG. 10A shows plan diagrams of a semiconductor device according to some embodiments.

FIG. 10B shows cross-sectional diagrams of a semiconductor device according to some embodiments, that illustrate cross-sectional surfaces taken long lines IV-IV′, V-V′, and VI-VI′ in FIG. 10A.

Referring to FIGS. 10A and 10B, in an embodiment, a semiconductor device 100i includes regions that have source/drain regions 150 with different depths. The substrate 101 includes a first region R1, a second region R2, and a third region R3. The first to third regions R1, R2, and R3 may be adjacent to each other or may be spaced apart from each other. Different types of transistors may be formed in the first to third regions R1, R2, and R3 of the substrate 101. For example, when an NMOS or PMOS transistor is formed in the first region R1, a PMOS or NMOS transistor is formed in the second region R2.

In an embodiment, the source/drain regions 150 have a first depth in the first region R1, a second depth different from the first depth in the second region R2, and a third depth different from the first and second depths in the third region R3. In another embodiment, as illustrated in FIGS. 8A to 8C, the lowermost ends of the source/drain regions 150 have different levels. For example, the lowermost ends of the source/drain regions 150 have different levels in the first region R1, and different levels in the second region R2 and the third region R3. The epitaxial layers 135 have a first thickness in the vertical direction in the first region R1, a second thickness in the vertical direction in the second region, and a third thickness in the vertical direction in the third region R3. The first to third thicknesses are different.

The number of the plurality of semiconductor layers 141, 142, and 143 that electrically connect the source/drain regions 150 to each other in the first region R1, the second region R2, and the third region R3 may be different. In an embodiment, in the first region R1, depending on the depth of source/drain regions 150, the second and third semiconductor layers 142 and 143 are used as channel layers. In the second region R2, the first semiconductor layer 141 is used as a channel layer. In the third region R3, the first to third semiconductor layers 141, 142, and 143 are used as channel layers.

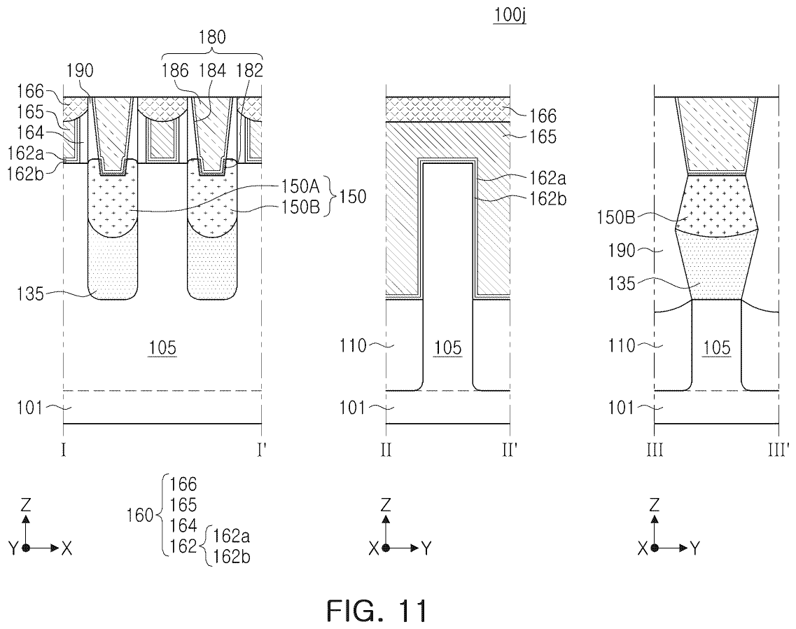

FIG. 11 shows cross-sectional diagrams of a semiconductor device according to an embodiment, and illustrate cross-sectional surfaces that correspond to the cross-sectional surfaces taken long lines I-I′, II-II′, and III-III′ as shown in FIG. 2.

In FIG. 11, the same reference numerals as those in FIG. 2 may indicate corresponding components, and repeated descriptions thereof may be omitted.

Referring to FIG. 11, in an embodiment, a semiconductor device 100j includes a substrate 101, an active region 105, a device isolation layer 110, a semiconductor structure 140, source/drain regions 150, gate structures 160, contact structures 180, and an interlayer insulating layer 190. The semiconductor device 100j includes FinFET devices in which the active region 105 is a transistor that has a fin structure. The FinFET devices include transistors disposed around the active region 105 and the gate structures 160 that cross each other. For example, the transistors may include NMOS transistors or PMOS transistors.

The source/drain regions 150 are disposed on both sides of the gate structures 160 and on recess regions in which the active region 105 is recessed. The recess region extends in the X-direction between the gate structures 160 and has internal sidewalls disposed at each end in the X-direction and a bottom surface between the internal sidewalls. In an embodiment, the source/drain regions 150 are formed by an ion implantation process (IIP). For example, the epitaxial layer 135, which is an undoped layer that does not include impurities, is formed in the recess region, and the source/drain regions 150 are formed on the epitaxial layer 135 through a process described with reference to FIG. 13H, described below. By adjusting the depth of the source/drain regions 150 through the ion implantation process (IIP), the channel region that electrically connects the source/drain regions 150 to each other can be adjusted. The source/drain regions 150 are provided as source regions or drain regions of transistors. As illustrated in FIG. 11, the upper surface of the source/drain regions 150 may be similar to the lower surface of the gate structures 160 or may be located at a level higher than a level of the lower surface of the gate structures 160. However, the relative levels of the source/drain regions 150 and the gate structures 160 can vary in other embodiments. For example, the source/drain regions 150 have a shape in which the upper surface is located at a level higher than a level of the lower surface of the gate structures 160, such as a level of the gate electrode layer 165, but embodiments thereof are not necessarily limited thereto.

The gate structures 160 cross the active region 105 and extend in a first direction, such as the Y-direction. The channel regions of transistors are formed in the active region 105 that crosses the gate structures 160. For example, the “channel region” includes a depletion region of a transistor, and crosses the gate structures 160 in the active region 105. The gate structure 160 include a gate dielectric layers 162, a gate electrode layer 165, spacer layers 161, and a gate capping layer 166.

The first and second gate dielectric layers 162a and 162b are disposed between the active region 105 and the gate electrode layer 165, with the second gate dielectric layer 162b being disposed on a lower surface and both side surfaces of the gate electrode layer 165, and the first gate dielectric layer 162a being disposed on the lower surface of the second gate dielectric layer 162b on the lower surface of the gate electrode layer 165. In embodiments, one of the first and second gate dielectric layers 162a and 162b is not omitted. The first and second gate dielectric layers 162a and 162b each include at least one of an oxide, a nitride, or a high-k material. The high-K material is a dielectric material that has a higher dielectric constant than a silicon oxide film (SiO2). The high-K material includes, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

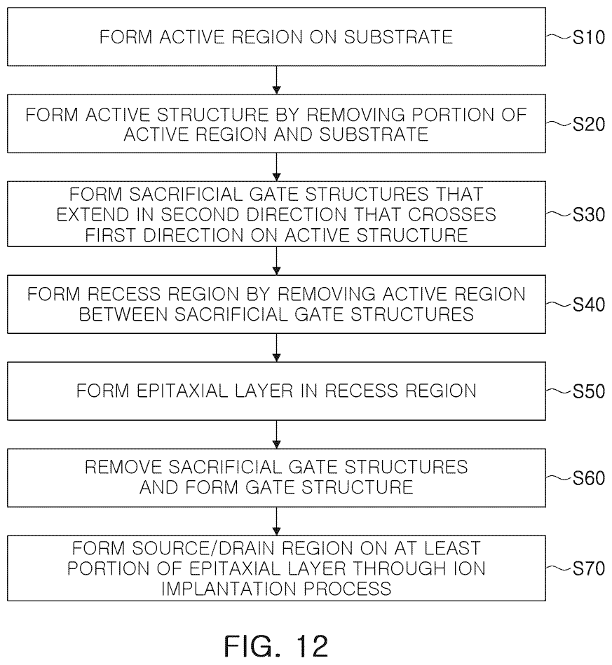

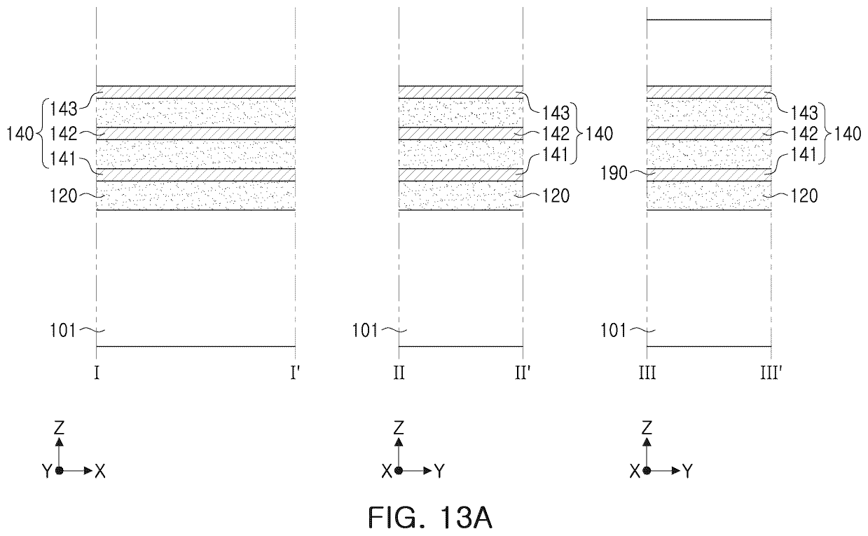

FIG. 12 is a flowchart of a method of manufacturing a semiconductor device according to an embodiment.

FIGS. 13A to 13H are cross-sectional diagrams that illustrate a method of manufacturing a semiconductor device according to an embodiment. FIGS. 13A to 13H illustrate an embodiment of a method of manufacturing the semiconductor device 100 in FIGS. 1 and 2, and illustrate cross-sectional surfaces corresponding to those shown in FIG. 2.

Referring to FIGS. 12 and 13A, in an embodiment, an active region 105 is formed on a substrate 101 (S10), and sacrificial layers 120 and the plurality of semiconductor layers 141, 142, and 143 are alternately stacked on the active region 105.

The sacrificial layers 120 are replaced with the gate dielectric layer 162 and the gate electrode 165 as illustrated in FIG. 2 through a subsequent process. The sacrificial layers 120 are formed of a material that has a etch selectivity with respect to the semiconductor layers 141, 142, and 143. The semiconductor layers 141, 142, and 143 include materials that differ from those of the sacrificial layers 120. In embodiments, the semiconductor layers 141, 142, and 143 include silicon (Si), and the sacrificial layers 120 include silicon germanium (SiGe).

The sacrificial layers 120 and the semiconductor layers 141, 142, and 143 are formed by performing an epitaxial growth process using the substrate 101 as a seed. Each of the sacrificial layers 120 and the semiconductor layers 141, 142, and 143 has a thickness that ranges from about 1 Å to about 100 nm. The number of the semiconductor layers 141, 142, and 143 alternately stacked with the sacrificial layer 120 can vary in other embodiments.

Referring to FIGS. 12 and 13B, in an embodiment, the active structures are formed by removing a portion of a stack structure of the sacrificial layers 120 and the semiconductor layers 141, 142, and 143, an active region 105, and the substrate 101 (S20).

The active structure includes the sacrificial layers 120 and the plurality of semiconductor layers 141, 142, and 143 alternately stacked, and a portion of the substrate 101 is removed such that an active region 105 is formed that protrudes from the upper surface of the substrate 101. The active structures have a line shape that extends in one direction, such as the X-direction, and are spaced apart from each other in the Y-direction. Depending on the aspect ratio, the active region 105 may have an inclined shape such that a width thereof increases toward the substrate 101.

An insulating material is filled in the region from which a portion of the substrate 101 is removed and the active region 105 is recessed to protrude, thereby forming the device isolation layers 110. An upper surface of the device isolation layers 110 is located at a level lower than an upper surface of the active region 105.

Referring to FIGS. 12 and 13C, in an embodiment, sacrificial gate structures 170 and the gate spacer layers 164 are formed on the active structures (S30).

The sacrificial gate structures 170 are sacrificial structures formed on the plurality of semiconductor layers 141, 142, and 143 in a region in which the gate dielectric layer 162 and the gate electrode 165 will be disposed through a subsequent process, as illustrated in FIG. 2. The sacrificial gate structures 170 include first and second sacrificial gate layers 172 and 175 and a mask pattern layer 176 stacked on the first and second sacrificial gate layers 172 and 175. The first and second sacrificial gate layers 172 and 175 are patterned using the mask pattern layer 176. The first and second sacrificial gate layers 172 and 175 include an insulating layer and a conductive layer, respectively. For example, the first sacrificial gate layer 172 includes silicon oxide, and the second sacrificial gate layer 175 includes polysilicon. The mask pattern layer 176 includes silicon nitride. The sacrificial gate structures 170 have a line shape that crosses the active structures and extend in one direction. The sacrificial gate structures 170 extend, for example, in the Y-direction and are spaced apart from each other in the X-direction.

The gate spacer layers 164 are formed on both sidewalls of the sacrificial gate structures 170. The gate spacer layers 164 are formed by forming a film of uniform thickness along the upper surface and side surfaces of the sacrificial gate structures 170 and the active structures and anisotropically etching the film. The gate spacer layers 164 are formed of a low dielectric constant material, and include, for example, at least one of SiO, SiN, SiCN, SiOC, SiON, or SiOCN.

Referring to FIGS. 12 and 13D, in an embodiment, a recess region RC is formed by partially removing the exposed sacrificial layers 120, the plurality of semiconductor layers 141, 142, 143 and the active region 105 between the sacrificial gate structures 170 (S40).

The recess region RC is formed by removing a portion of the exposed sacrificial layers 120 and portions of the plurality of semiconductor layers 141, 142, and 143 using the sacrificial gate structures 170 and the gate spacer layers 164 as a mask. The recess process is performed by, for example, sequentially applying a dry etching process and a wet etching process. For example, recess region RC is formed in a vertical direction through a dry etching process, and the recess region RC is formed in a horizontal direction through a wet etching process. Accordingly, the plurality of semiconductor layers 141, 142, and 143 have a limited length in the X-direction. However, the specific shapes of the side surfaces of the plurality of semiconductor layers 141, 142, and 143 and the upper portion of the active region 105 are not necessarily limited to the examples illustrated in FIG. 13D

Referring to FIGS. 12 and 13E, in an embodiment, an epitaxial layer 135 is formed that fills the recess region RC (S50).

The epitaxial layer 135 is formed by an epitaxial growth process. In an embodiment, the epitaxial layer 135 is an undoped layer that does not include impurities. For example, the epitaxial layer 135 includes silicon (Si) or silicon germanium (SiGe). The epitaxial layer 135 is in contact with the plurality of semiconductor layers 141, 142, 143 and the gate structures 160. In an embodiment, a surface of the epitaxial layer 135 that is opposite to the plurality of semiconductor layers 141, 142, 143 and the sacrificial layers 120 has a wavy shape. The upper surface of the epitaxial layer 135 is located at substantially the same level as the lower surface of the gate structures 160 or at a level higher than the lower surface of the gate structures 160, but an embodiment thereof is not limited thereto.

To manufacture the semiconductor device 100d in FIG. 7, in a process of forming the epitaxial layer 135, the epitaxial layer 135 is not formed as an undoped layer, and impurities of a different conductivity-type from the impurities included in the source/drain regions 150 are included by in-situ doping. For example, the epitaxial layer 135 includes at least one of boron (B), aluminum (Al), gallium (Ga), indium (In), or thallium (TI), which are P-type impurities. The source/drain regions 150 described below include at least one of phosphorus (P), arsenic (As), or antimony (Sb), which are N-type impurities. However, embodiments thereof are not necessarily limited thereto, and in other embodiments, the epitaxial layer 135 includes N-type impurities, and the source/drain regions 150 include P-type impurities.

Referring to FIGS. 12 and 13F, in an embodiment, an interlayer insulating layer 190 is formed, and the sacrificial layers 120 and the sacrificial gate structures 170 are removed (S60).

The interlayer insulating layer 190 IS formed by forming an insulating film that covers the sacrificial gate structures 170 and the epitaxial layer 135 and performing a planarization process.

The sacrificial layers 120 are sacrificial gate structures 170 are selectively removed with respect to the gate spacer layers 164, the interlayer insulating layer 190, and the plurality of semiconductor layers 141, 142, and 143. For example, upper gap regions UR are formed by removing the sacrificial gate structures 170, and lower gap regions LR are formed by removing the sacrificial layers 120 exposed through the upper gap regions UR. For example, when the sacrificial layers 120 include silicon germanium (SiGe) and the plurality of semiconductor layers 141, 142, and 143 include silicon (Si), the sacrificial layers 120 are selectively removed by performing a wet etching process that use peracetic acid solution (NH₄OH:H₂O₂:H₂O=1:1:5) used in the standard clean-1 (SC1) cleaning process as an etchant . . .

Referring to FIGS. 12 and 13G, in an embodiment, a gate structure 160 is formed in upper gap regions UR and lower gap regions LR (S60).

The gate dielectric layer 162 is formed to conformally cover internal surfaces of the upper gap regions UR and the lower gap regions LR. The gate electrode 165 is formed to fill the upper gap regions UR and the lower gap regions LR. The gate electrode 165 and the gate spacer layers 164 are removed to a predetermined depth from an upper portion of the upper gap regions UR. In the upper gap regions UR, a gate capping layer 166 is formed in a region from which the gate electrode 165 and the gate spacer layers 164 are removed. Accordingly, a gate structure 160 that includes the gate dielectric layer 162, the gate electrode 165, and the gate spacer layers 164, and the gate capping layer 166 is formed.

Referring to FIGS. 12 and 13H, in an embodiment, a source/drain region 150 is formed by performing an ion implantation process (IIP) on the epitaxial layer 135 (S70).

Impurities are implanted into at least a portion of the epitaxial layer 135 through an ion implantation process (IIP). Depending on the conditions of the ion implantation process (IIP), the type, concentration, distribution, and depth of impurities can be targeted and controlled. In an ion implantation process (IIP), the concentration distribution of impurities can be artificially controlled through multiple implantations. The ion implantation process (IIP) can be performed by adjusting the dose of ions. The ion implantation process (IIP) is performed by adjusting the tilt, rotation, and type of impurities. By forming the source/drain region 150 by an ion implantation process (IIP), process costs can be reduced and the process can be simplified as compared to other processes. In addition, the depth of the source/drain region 150 can be adjusted.

In an embodiment, to use the third semiconductor layer 143 that electrically connects the source/drain regions 150 as a channel layer, the level of the lowermost end of the source/drain regions 150 should be lower than the lower surface of the third semiconductor layer 143. For example, the ion implantation process (IIP) on the epitaxial layer 135 is performed at a power of about 1 keV to about 10 keV.

In an embodiment, to use the second semiconductor layer 142 and the third semiconductor layer 143 that electrically connect the source/drain regions 150 to each other as a channel layer, a level of the lowermost end of the source/drain regions 150 should be lower than the lower surface of the second semiconductor layer 142. For example, the ion implantation process (IIP) on the epitaxial layer 135 is performed at a power of about 15 keV to about 30 keV.

In an embodiment, to use the first to third semiconductor layers 141, 142, and 143 that electrically connect the source/drain regions 150 to each other as a channel layer, a level of a lowermost end of the source/drain regions 150 should be lower than the lower surface of the first semiconductor layer 141. For example, the ion implantation process (IIP) on the epitaxial layer 135 is performed at a power of about 35 keV or more.

In an embodiment, an ion implantation process (IIP) on epitaxial layers 135 can use different ion implantation energies. For example, as illustrated in FIG. 10B, a first ion implantation energy is used in the first region R1, a second ion implantation energy that differs from the first ion implantation energy is used in the second region R2, and a third ion implantation energy that differs from the first and second ion implantation energies is used in the third region R3. Accordingly, the source/drain regions 150 have a first depth in the first region R1, a second depth that differs from the first depth in the second region R2, and a third depth that differs from the first and second depths in the third region R3. By adjusting the depth of the source/drain regions 150, as illustrated in FIG. 10B, the number of semiconductor layers 141, 142, and 143 that electrically connect the source/drain regions 150 to each other in the first region R1, the number of semiconductor layers 141, 142, and 143 that electrically connect the source/drain regions 150 to each other in the second region R2, and the number of semiconductor layers 141, 142, and 143 that electrically connect the source/drain regions 150 to each other in the third region R3 can differ.

The above numerical values are examples, and can vary depending on conditions of the ion implantation process (IIP), and can vary depending on a desired depth of the plurality of semiconductor layers 141, 142, and 143 to be used as the channel layer. In an embodiment, the source/drain regions 150 are formed by performing the ion implantation process (IIP), such that depending on various conditions of the ion implantation process (IIP), the semiconductor layers to be used as a channel layer can be selected from the plurality of semiconductor layers 141, 142, and 143.

Thereafter, referring to FIG. 2, contact structures 180 are formed. The contact structures 180 include a first metal-semiconductor compound layer 182 disposed on a lower end, a barrier layer 184 disposed along sidewalls, and a plug conductive layer 186 that fills a space defined by the barrier layer 184.

For example, contact holes that expose the source/drain regions 150 are formed by patterning the interlayer insulating layer 190. The contact structures 180 are formed by filling the contact holes with a conductive material. For example, a material included in the barrier layer 184 is deposited in the contact holes, and a first metal-semiconductor compound layer 182, such as a silicide layer, is formed on a lower end by performing a silicide process. Thereafter, contact structures 180 are formed by depositing a conductive material that fills the contact holes. Accordingly, the semiconductor device 100 in FIGS. 1 and 2 can be manufactured.

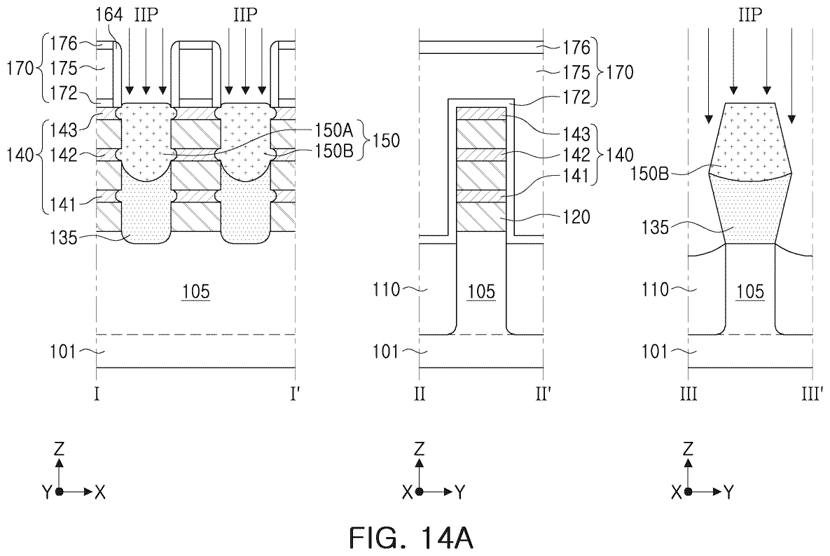

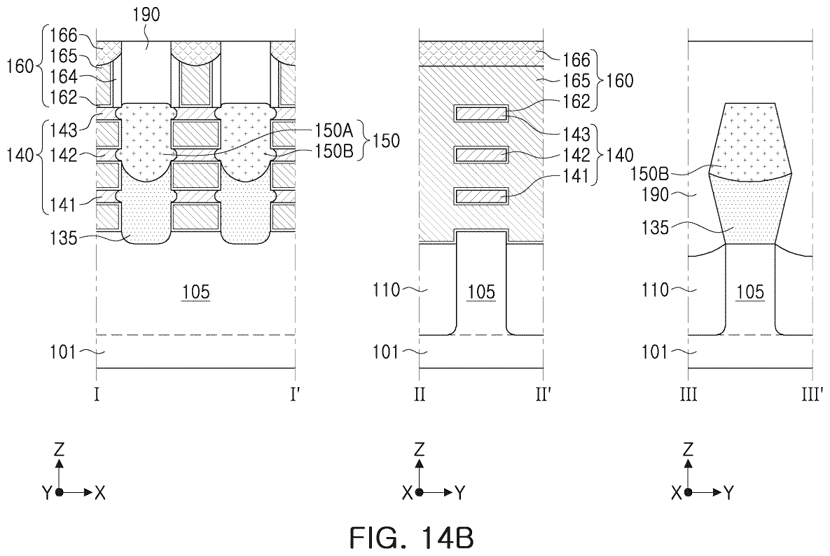

FIGS. 14A and 14B show cross-sectional diagrams that illustrate a method of manufacturing a semiconductor device in order according to an embodiment. For example, FIGS. 14A and 14B illustrate an embodiment of a method of manufacturing the semiconductor device 100 in FIGS. 1 and 2, and cross-sectional surfaces that correspond to those shown in FIG. 2.

In the following, descriptions of components described above with reference to FIGS. 13A to 13H are omitted.

For example, the same process as those described with reference to FIGS. 13A to 13E are performed.

Referring to FIG. 14A, in an embodiment, a source/drain region 150 is formed by performing an ion implantation process (IIP) on the epitaxial layer 135.

An ion implantation process (IIP) is performed before the forming the gate structure 160. In an embodiment, the source/drain regions 150 are formed on the epitaxial layer 135 through the ion implantation process (IIP) before forming the interlayer insulating layer 190 that covers the epitaxial layer 135. The description in FIG. 13H, above, applies to the ion implantation process (IIP). The ion implantation process (IIP) may be performed before and/or after forming the gate structure 160.

Referring to FIG. 14B, in an embodiment, a gate structure 160 is formed by forming an interlayer insulating layer 190 that covers the source/drain regions 150 and removing sacrificial layers 120 and sacrificial gate structures 170. This process is substantially the same as the processes described with reference to FIGS. 13F and 13G.

By forming the contact structures 180, the semiconductor device 100 as illustrated in FIGS. 1 and 2 can be manufactured.

According to embodiments, by forming source/drain regions through an ion implantation process, and selecting one or more of a plurality of semiconductor layers to be used as a channel layer by varying the depth of the source/drain regions, current control capability is increased, and a semiconductor device having increased performance, electrical properties and reliability is provided.

While embodiments have been illustrated and described above, it is apparent to those skilled in the art that modifications and variations can be made without departing from the scope of the described embodiments as defined by the appended claims.

1. A semiconductor device, comprising:
an active region that extends on a substrate in a first direction;
a plurality of semiconductor layers disposed on the active region and that are spaced apart from each other in a vertical direction perpendicular to an upper surface of the substrate;
a gate structure disposed on the substrate and that crosses the active region and the plurality of semiconductor layers, surrounds each of the plurality of semiconductor layers, and extends in a second direction that crosses the first direction;
a source/drain region disposed on at least one side of the gate structure and in contact with a portion of the plurality of semiconductor layers; and
an epitaxial layer that is spaced apart from an uppermost semiconductor layer of the plurality of semiconductor layers, is disposed below the source/drain region and between the active region and the source/drain region, and is in contact with at least a portion of the side surfaces of a lowermost semiconductor layer of the plurality of semiconductor layers.

2. The semiconductor device of claim 1, wherein the epitaxial layer is an undoped layer.

3. The semiconductor device of claim 1, wherein cross-sectional surfaces of the source/drain region and the epitaxial layer in the second direction form at least one of a pentagonal shape, a hexagonal shape, an elliptical shape, or a circular shape.

4. The semiconductor device of claim 1, wherein the epitaxial layer is in contact with at least a portion of side surfaces of a second-lowermost semiconductor layer adjacent to the lowermost semiconductor layer.

5. The semiconductor device of claim 1, wherein the epitaxial layer is recessed into an upper portion of the active region.

6. The semiconductor device of claim 1,
wherein the source/drain region and the epitaxial layer include elements of different groups of the periodic table of elements,
wherein the source/drain region includes first impurities that include one of a group 13 element or a group 15 element in the periodic table of elements, and
wherein the epitaxial layer includes second impurities that include another element of the group 13 elements or the group 15 elements.

7. The semiconductor device of claim 6,
wherein the epitaxial layer further includes the first impurities, and
a concentration of the first impurities in the source/drain region is higher than a concentration of the first impurities in the epitaxial layer.

8. The semiconductor device of claim 7,
wherein the source/drain region further includes the second impurities, and
a concentration of the second impurities in the epitaxial layer is higher than a concentration of the second impurities in the source/drain region.

9. The semiconductor device of claim 1, further comprising:
internal spacer layers disposed on each side of the gate structure in the first direction.

10. The semiconductor device of claim 1,
wherein the plurality of semiconductor layers include a first semiconductor layer that is a lowermost semiconductor layer, a second semiconductor layer that is a second-lowermost semiconductor layer adjacent to the first semiconductor layer, and a third semiconductor layer that is an uppermost semiconductor layer, and
a level of a lowermost end of the source/drain region is lower than a lower surface of the third semiconductor layer.

11. The semiconductor device of claim 10, wherein a level of the lowermost end of the source/drain region is lower than a lower surface of the second semiconductor layer.

12. The semiconductor device of claim 1, further comprising:
a backside contact structure that penetrates through the epitaxial layer and is connected to the source/drain region below the epitaxial layer.

13. A semiconductor device, comprising:
an active region that extends on the substrate in a first direction;
a plurality of semiconductor layers disposed on the active region and that are spaced apart from each other in a vertical direction perpendicular to an upper surface of the substrate;
a gate structure disposed on the substrate and that crosses the active region and the plurality of semiconductor layers, surrounds each of the plurality of semiconductor layers, and extends in a second direction that crosses the first direction;
source/drain regions disposed on at least one side of the gate structure and in contact with at least a portion of the plurality of semiconductor layers; and
epitaxial layers disposed between the active region and the source/drain regions, respectively,
wherein the source/drain regions include a first source/drain region and a second source/drain region disposed on each side of the gate structure, and
wherein the epitaxial layers are recessed into the active region and extend from an upper surface of the active region to a lower surface of the source/drain regions.

14. The semiconductor device of claim 13, wherein a level of a lowermost end of the first source/drain region is the same as a level of a lowermost end of the second source/drain region.

15. The semiconductor device of claim 13, wherein a level of a lowermost end of the first source/drain region differs from a level of a lowermost end of the second source/drain region.

16. The semiconductor device of claim 13, wherein the first source/drain region and the second source/drain region are electrically connected to each other by those semiconductor layers of the plurality of semiconductor layers that are disposed higher than a higher of a level of a lowermost end of the first source/drain region and a level of a lowermost end of the second source/drain region.

17. The semiconductor device of claim 13, wherein the source/drain regions and the epitaxial layers include impurities of different conductivity-types.

18. A semiconductor device, comprising:
a substrate that includes a first region and a second region;
an active region that extends on the substrate in a first direction;
a plurality of semiconductor layers disposed on the active region and that spaced apart from each other in a vertical direction perpendicular to an upper surface of the substrate;
a gate structure disposed on the substrate and that crosses the active region and the plurality of semiconductor layers, surrounds each of the plurality of semiconductor layers, and extends in a second direction that crosses the first direction;
source/drain regions disposed on at least one side of the gate structure and in contact with at least a portion of the plurality of semiconductor layers; and
epitaxial layers disposed between the active region and the source/drain regions, respectively,
wherein, in the first region, the source/drain regions have a first depth in the vertical direction,
wherein, in the second region, the source/drain regions have a second depth in the vertical direction that differs from the first depth,
wherein a number of the plurality of semiconductor layers that electrically connect the source/drain regions to each other in the first region differs from a number of the plurality of semiconductor layers that electrically connect the source/drain regions to each other in the second region, and
wherein the epitaxial layers are recessed into the active region and extend from an upper surface of the active region to a lower surface of the source/drain regions.

19. The semiconductor device of claim 18, wherein the epitaxial layers have a first thickness in the vertical direction in the first region and a second thickness in the vertical direction in the second region that differs from the first thickness.

20. The semiconductor device of claim 18,
wherein, in the first region, lowermost ends of the source/drain regions have different levels, and
wherein, in the second region, lowermost ends of the source/drain regions have different levels.

21. (canceled)

22. (canceled)
